(19) United States
(12) Patent Application Publication
(10) Pub. No.: US 2025/0183214 A1
(43) Pub. Date: Jun. 5, 2025

(54) SEMICONDUCTOR PACKAGE

(71) Applicant: Samsung Electronics Co., Ltd., Suwon-si (KR)

(72) Inventors: SEUNGSOO HA, Suwon-si (KR); Seunggeol Ryu, Suwon-si (KR); HONGWON KIM, Suwon-si (KR); EUNSEOK CHO, Suwon-Si (KR); JAE-HOON CHOI, Suwon-si (KR)

(21) Appl. No.: 18/828,118

(22) Filed: Sep. 9, 2024

(30) Foreign Application Priority Data
Dec. 5, 2023 (KR) 10-2023-0174432
Feb. 7, 2024 (KR) 10-2024-0019067

(51) Int. Cl. H01L 23/00; H01L 23/31; H01L 23/36; H01L 23/538; H01L 25/16

(52) U.S. Cl. CPC H01L 24/24; H01L 23/36; H01L 23/5385; H01L 25/162; H01L 23/3107; H01L 2224/24226

(57) ABSTRACT

A semiconductor package including a first semiconductor package that includes a redistribution layer, a substrate disposed on the redistribution layer and including a plurality of wiring layers, a first semiconductor chip disposed on the redistribution layer, and an encapsulant covering at least a portion of each of the substrate and the first semiconductor chip; and a second semiconductor package that is disposed on the first semiconductor package and includes a second semiconductor chip. The first semiconductor package includes a first side surface and a second side surface facing the first side surface. The plurality of wiring layers are disposed adjacent to the first side surface, the first semiconductor chip is disposed between the plurality of wiring layers and the second side surface, and a distance between the first semiconductor chip and the first side surface is greater than a distance between the first semiconductor chip and the second side surface.

### CROSS-REFERENCE TO RELATED APPLICATION

This application claims the benefit of priority under 35 U.S.C. § 119 to Korean Patent Application No. 10-2023-0174432 filed at the Korean Intellectual Property Office on Dec. 5, 2023, and Korean Patent Application No. 10-2024-0019067 filed at the Korean Intellectual Property Office on Feb. 7, 2024, the entire contents of which are incorporated herein by reference.

### BACKGROUND OF THE INVENTION

### (a) Field of the Invention

The present disclosure relates to a semiconductor package.

### (b) Description of the Related Art

In a semiconductor package industry, a semiconductor package structure with a package-on-package (POP) type that stacks an upper package on a lower package and electrically connects the upper package to the lower package is known. The package-on-package structure is useful because it may reduce a mounting area of the package. For electrical connection between the upper package and the lower package, a backside redistribution layer (BRDL) may be formed on the lower package, or an interposer substrate may be disposed on the lower package. The backside redistribution layer or the interposer substrate may be connected to a signal, a power line, and the like of the upper package.

In the package-on-package structure, a heat dissipation performance of the lower package may be limited due to a presence of the upper package. In addition, a thickness of a semiconductor chip of the lower package may be limited to secure a space for the backside redistribution layer, and limitation in the thickness of the semiconductor chip may be a factor that hinders the heat dissipation performance of the lower package. In addition, introduction of an additional process for forming the backside redistribution layer or the interposer substrate may lengthen a turn-around time (TAT), and may increase the number of process steps.

### SUMMARY OF THE INVENTION

An aspect of the present disclosure is to provide a semiconductor package with an improved heat dissipation characteristic.

Another aspect of the present disclosure is to provide a semiconductor package capable of reducing a turn-around time (TAT) (or a process time) and the number of process steps.

A semiconductor package according to an embodiment of the present disclosure includes: a first semiconductor package that includes a redistribution layer, a substrate disposed on the redistribution layer and including a plurality of wiring layers, a first semiconductor chip disposed on the redistribution layer, and an encapsulant covering at least a portion of each of the substrate and the first semiconductor chip; and a second semiconductor package that is disposed on the first semiconductor package and includes a second semiconductor chip. The first semiconductor package includes a first side surface and a second side surface facing the first side surface. The plurality of wiring layers are disposed adjacent to the first side surface of the first semiconductor package, the first semiconductor chip is disposed between the plurality of wiring layers and the second side surface of the first semiconductor package, and a distance between the first semiconductor chip and the first side surface of the first semiconductor package is greater than a distance between the first semiconductor chip and the second side surface of the first semiconductor package.

A semiconductor package according to another embodiment of the present disclosure includes: a first semiconductor package that includes a redistribution layer, a first substrate that is disposed on the redistribution layer to be electrically connected to the redistribution layer and includes a plurality of insulating layers and a plurality of wiring layers, a first semiconductor chip disposed on the redistribution layer and electrically connected to the redistribution layer, and a first encapsulant covering at least a portion of each of the first substrate and the first semiconductor chip; and a second semiconductor package that is disposed on the first semiconductor package and includes a second substrate, a second semiconductor chip disposed on a first surface of the second substrate to be electrically connected to the second substrate, a second encapsulant covering the second semiconductor chip, and a conductive bump disposed on the a second surface of the second substrate. The first encapsulant does not cover a wiring layer among the plurality of wiring layers closest to the second semiconductor package, the conductive bump contacts the wiring layer not covered by the first encapsulant to electrically connect the second semiconductor package to the first substrate, and at least a portion of the first semiconductor chip does not overlap the second semiconductor package in a vertical direction.

A semiconductor package according to another embodiment of the present disclosure includes: a first semiconductor package that includes a redistribution layer, a substrate disposed on the redistribution layer and electrically connected to the redistribution layer, a first semiconductor chip disposed on the redistribution layer and electrically connected to the redistribution layer, and an encapsulant covering at least a portion of each of the substrate and the first semiconductor chip; a second semiconductor package that is disposed on the first semiconductor package to be electrically connected to the substrate and includes a second semiconductor chip; and a heat dissipation structure that is disposed side by side with the second semiconductor package above the first semiconductor package. At least a portion of the second semiconductor package is disposed above the substrate, and at least a portion of the heat dissipation structure is disposed above the first semiconductor chip.

According to the aspect of the present disclosure, a semiconductor package with an improved heat dissipation characteristic may be provided.

According to the other aspect of the present disclosure, a semiconductor package capable of reducing a turn-around time and the number of process steps may be provided.

### BRIEF DESCRIPTION OF THE DRAWINGS

FIG. 1 is a cross-sectional view of a semiconductor package according to an embodiment of the present disclosure.

FIG. 2 is a plan view of the semiconductor package of FIG. 1 cut along a direction (or a line) I-I′.

FIG. 3 is a cross-sectional view of a semiconductor package according to an embodiment of the present disclosure.

FIG. 4 is a plan view of the semiconductor package of FIG. 3 cut in a direction I-I′.

FIG. 5 is a cross-sectional view of a semiconductor package according to an embodiment of the present disclosure.

FIG. 6 is a cross-sectional view of a semiconductor package according to an embodiment of the present disclosure.

FIG. 7 is a cross-sectional view of a semiconductor package according to an embodiment of the present disclosure.

FIGS. 8 to 15 are views for describing a manufacturing process of the semiconductor package of FIG. 5.

### DETAILED DESCRIPTION OF THE EMBODIMENTS

Embodiments of the present disclosure will be described more fully hereinafter with reference to the accompanying drawings so that those skilled in the art may easily implement the embodiments. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element is referred to as being “connected” or “coupled” to or “on” another element, it can be directly connected or coupled to or on the other element or intervening elements may be present. In a similar sense, this includes being “physically connected” as well as being “electrically connected”. In contrast, when an element is referred to as being “directly connected” or “directly coupled” to another element, or as “contacting,” “in contact with,” or “contact” another element, there are no intervening elements present at the point of contact. In addition, unless explicitly described to the contrary, the word “comprise” and variations such as “comprises” or “comprising” will be understood to imply the inclusion of stated elements but not the exclusion of any other elements.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, throughout the specification, sequential numbers such as 1st and 2nd are used to distinguish a certain component from another component that is the same or similar to the same, and are not necessarily intended to refer to a specific component. Accordingly, a component referred to as a first component in a specific portion of the specification may be referred to as a second component in another portion of the specification.

Additionally, throughout the specification, a singular reference to a component includes references to a plurality of these components, unless specifically stated to the contrary. For example, “an insulating layer” may be used to mean not only one insulating layer but also a plurality of insulating layers such as two, three, or more insulating layers.

In addition, throughout the specification, references to one surface and the other surface are intended to distinguish different surfaces from each other, and are not necessarily intended to limit it to a specific surface. Accordingly, a surface referred to as one surface in a specific portion of the specification may be referred to as the other surface in another portion of the specification.

Hereinafter, a semiconductor package according to embodiments of the present disclosure will be described with reference to the drawings.

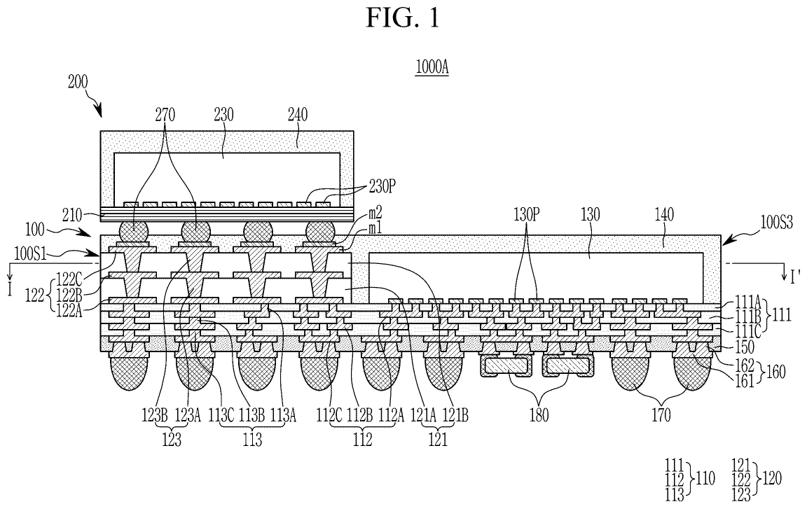

FIG. 1 is a cross-sectional view of a semiconductor package according to an embodiment of the present disclosure.

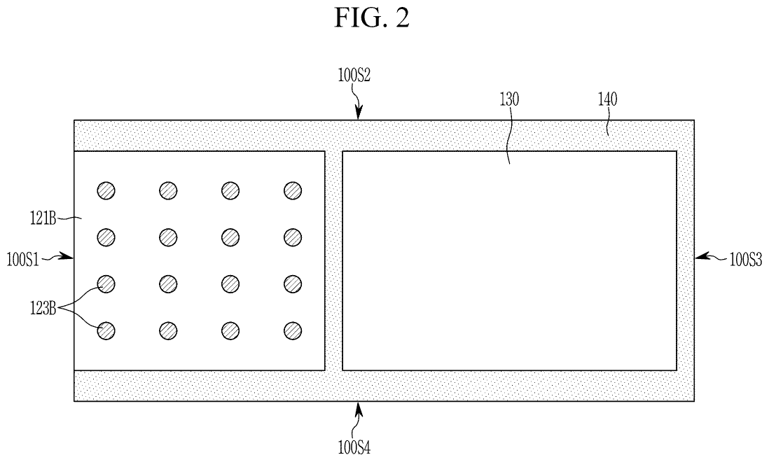

FIG. 2 is a plan view of the semiconductor package of FIG. 1 cut along a direction (or a line) I-I′.

Referring to FIG. 1, the semiconductor package 1000A may include a first semiconductor package 100 and a second semiconductor package 200 disposed on the first semiconductor package 100.

The first semiconductor package 100 includes a redistribution layer (or a redistribution structure) 110, a first substrate 120, a first semiconductor chip 130 disposed on one (i.e., first) surface of the redistribution layer 110, and a first encapsulant (or a first sealant) 140 that covers at least a portion of each of the first substrate 120 and the first semiconductor chip 130. Additionally, the first semiconductor package 100 may further include at least one of a protective layer 150, an under bump structure 160, a first conductive bump 170, and a passive element 180 that are disposed above or on the other (i.e., second) surface of the redistribution layer 110.

The second semiconductor package 200 may include a second substrate 210, a second semiconductor chip 230 disposed on one (i.e., first) surface of the second substrate 210 to be electrically connected to the second substrate 210, a second encapsulant 240 covering the second semiconductor chip 230, and a second conductive bump 270 disposed on the other (i.e., second) surface of the second substrate 210.

In the present disclosure, the second semiconductor package 200 may be disposed on the first semiconductor package 100 so that at least a portion of the second semiconductor package 200 is disposed above the first substrate 120, and the second semiconductor package 200 may be electrically connected to the first substrate 120 of the first semiconductor package 100. For example, the second semiconductor package 200 may be disposed on the first semiconductor package 100 so that an entire second semiconductor package 200 is disposed above the first substrate 120. The second semiconductor package 200 may be redistributed through the first substrate 120, and another configuration (e.g., a backside redistribution layer (or a backside redistribution structure) or an interposer substrate) for electrical connection between the first semiconductor package 100 and the second semiconductor package 200 may not be necessary. Therefore, according to the present disclosure, a thickness of the first semiconductor chip 130 may be increased compared with the semiconductor package having the same size, and the semiconductor package 1000A capable of efficiently dissipating a heat generated from the first semiconductor chip 130 to the outside of the package may be provided. In addition, the semiconductor package 1000A capable of reducing a turn-around time (TAT) (or a process time) and the number of process steps may be provided.

The second semiconductor package 200 may be disposed to deviate from the first semiconductor chip 130, so that it is not disposed above the first semiconductor chip 130. Therefore, the first semiconductor chip 130 may not overlap the second semiconductor package 200. In the present disclosure, the overlapping means overlapping in a vertical direction (e.g., a direction in which the first semiconductor package 100 and the second semiconductor package 200 are stacked based on the drawings). However, depending on a size of the second semiconductor package 200, the second semiconductor package 200 may include some regions disposed above the first semiconductor chip 130. Even in this case, in order to improve a heat dissipation characteristic, a region of the first semiconductor chip 130 overlapping the second semiconductor package 200 may be minimized.

The redistribution layer 110 may be electrically connected to each of the first substrate 120 and the first semiconductor chip 130, and may redistribute a connection pad 130P of the first semiconductor chip 130.

The redistribution layer 110 may include a plurality of insulating layers 111, a plurality of redistribution layers 112, and vias 113 for electrically connecting the plurality of redistribution layers 112 to each other. For example, the redistribution layer 110 may include a first insulating layer 111A, a first redistribution layer 112A disposed on the first insulating layer 111A, first vias 113A penetrating the first insulating layer 111A to electrically connect the first redistribution layer 112A to the first substrate 120 or the first semiconductor chip 130, a second insulating layer 111B disposed on the first insulating layer 111A to cover the first redistribution layer 112A, a second redistribution layer 112B disposed on the second insulating layer 111B, second vias 113B penetrating the second insulating layer 111B to electrically connect the second redistribution layer 112B to the first redistribution layer 112A, a third insulating layer 111C disposed on the second insulating layer 111B to cover the second redistribution layer 112B, a third redistribution layer 112C disposed on the third insulating layer 111C, and third vias 113C penetrating the third insulating layer 111C to electrically connect the third redistribution layer 112C to the second redistribution layer 112B. However, the number of the insulating layers 111, the redistribution layers 112, and the vias 113 included in the redistribution layer 110 is not limited to the number shown in the drawings.

The first insulating layer 111A disposed at an uppermost side of the redistribution layer 110 may contact each of the first substrate 120 and the first semiconductor chip 130. In addition, each of the first vias 113A disposed at an uppermost side of the redistribution layer 110 may contact a first wiring layer 122A of the first substrate 120 or the connection pad 130P of the first semiconductor chip 130 to electrically connect the first wiring layer 122A of the first substrate 120 or the connection pad 130P of the first semiconductor chip 130 to the first redistribution layer 112A.

An insulating material (for example, a photo-imageable dielectric (PID) that may be applied to a photolithography process) may be used as a material of each of the plurality of insulating layers 111. When the insulating layer 111 is formed of a photosensitive insulating material, a fine pitch may be realized through a photo via. The plurality of insulating layers 111 may or may not have boundaries that may be visually identifiable depending on a material of each of the plurality of insulating layers 111.

A conductive material may be used as a material of each of the plurality of redistribution layers 112 and the plurality of vias 113, and for example, each of the plurality of redistribution layers 112 and the plurality of vias 113 may include or may be formed of aluminum (Al), copper (Cu), gold (Au), silver (Ag), platinum (Pt), tin (Sn), chromium (Cr), palladium (Pd), lead (Pb), titanium (Ti), or an alloy thereof. The redistribution layer 112 and the via 113 may be integrally formed through the same process. Each of the plurality of vias 113 may have a tapered shape in which a width thereof narrows in a direction from one side to the other side, a cylindrical shape, or the like depending on a formation method thereof, a formation direction thereof, or the like. Each of the plurality of vias 113 may be a photo via, and the plurality of vias 113 may have a diameter and/or an interval narrower than that of vias 123 of the first substrate 120.

The first substrate 120 may be disposed on one surface of the redistribution layer 110, and may be electrically connected to the redistribution layer 110. Additionally, the first substrate 120 may be electrically connected to the second semiconductor package 200, and may route a signal, power, or the like transferred from the second semiconductor package 200. According to the present disclosure, the first semiconductor package 100 and the second semiconductor package 200 may be electrically connected through the first substrate 120 without a backside redistribution layer or an interposer substrate.

The first substrate 120 may include a plurality of insulating layers 121, a plurality of wiring layers 122, and the vias 123 for electrically connecting the plurality of wiring layers 122. Because the first substrate 120 includes the plurality of wiring layers 122, a degree of freedom in wiring design may be secured. For example, as shown in the drawings, the first substrate 120 may include the first wiring layer 122A, a first insulating layer 121A covering the first wiring layer 122A, a second wiring layer 122B disposed on the first insulating layer 121A, first vias 123A penetrating the first insulating layer 121A to electrically connect the second wiring layer 122B to the first wiring layer 122A, a second insulating layer 121B covering the second wiring layer 122B, a third wiring layer 122C disposed on the second insulating layer 121B, and second vias 123B penetrating the second insulating layer 121B to electrically connect the third wiring layer 122C to the second wiring layer 122B. However, the number of the insulating layers 121, the wiring layers 122, and the vias 123 included in the first substrate 120 is not limited to the number shown in the drawings.

The first substrate 120 may have an embedded trace substrate (ETS) structure. When the first substrate 120 has the ETS structure, one surface and a side surface of the first wiring layer 122A that is disposed at a lowermost side of the wiring layers 122 of the first substrate 120 may be covered with the first insulating layer 121A, and the other surface of the first wiring layer 122A may be coplanar with the one surface of the first insulating layer 121A. In the present disclosure, the term “coplanar” means being disposed at substantially the same level, and includes not only the exact same case but also a case where there is a fine level difference that may be caused by an error in a process. Additionally, the third wiring layer 122C that is closest to the second semiconductor package 200 or is disposed at an uppermost side of the third wiring layer 122C among the wiring layers 122 of the first substrate 120 may be exposed through (i.e., not covered by) the first encapsulant 140. As described later, the third wiring layer 122C may be exposed through the first encapsulant 140 by removing a portion of the first encapsulant 140 through laser processing or the like. The second conductive bump 270 of the second semiconductor package 200 may be directly disposed above the third wiring layer 122C exposed through the first encapsulant 140.

A region among the third wiring layer 122C exposed through the first encapsulant 140 may include a plurality of conductive layers m1 and m2, which may respectively include or may be formed of different materials. For example, the region among the third wiring layer 122C exposed through the first encapsulant 140 may include the first conductive layer m1 and the second conductive layer m2 disposed on the first conductive layer m1. The second conductive layer m2 may perform roles such as prevention of corrosion and oxidation of the third wiring layer 122C, improvement of an electric characteristic of the third wiring layer 122C, and improvement of a bonding force between the third wiring layer 122C and the first encapsulant 140. If necessary, the first conductive layer m1 and/or the second conductive layer m2 may include a plurality of metal layers. For example, the first conductive layer m1 may include a copper seed layer formed by electroless plating and a copper plating layer formed by electroplating on the copper seed layer. Additionally, the second conductive layer m2 may include a nickel (Ni) layer and a gold (Au) layer disposed on the nickel (Ni) layer. On a cross-section, a diameter of the second conductive layer m2 may be smaller than a diameter of the first conductive layer m1, but the present disclosure is not limited thereto. A region of the third wiring layer 122C covered with the first encapsulant 140 may include only the first conductive layer m1 and may not include the second conductive layer m2, but may include both the first conductive layer m1 and the second conductive layer m2.

A surface of the first substrate 120 facing the redistribution layer 110 and a surface of the first semiconductor chip 130 facing the redistribution layer 110 may be coplanar. As described later, the first substrate 120 and the first semiconductor chip 130 may be disposed on the same carrier substrate and may be molded with the first encapsulant 140, so that one surface of the molded first substrate and one surface of the molded first semiconductor chip are coplanar.

Referring to FIG. 2, the first semiconductor package 100 may have a first side surface 100S1, a second side surface 100S2, a third side surface 100S3, and a fourth side surface 100S4 that are sequentially disposed along a circumference thereof. The first side surface 100S1 and the third side surface 100S3 may face each other, and the second side surface 100S2 and the fourth side surface 100S4 may connect the first side surface 100S1 and the third side surface 100S3, respectively, and may face each other. In the present disclosure, the wiring layers 122 of the first substrate 120 may be disposed adjacent to the first side surface 100S1 among the first side surface 100S1 and the third side surface 100S3 of the first semiconductor package 100. For example, the wiring layers 122 of the first substrate 120 may exist between the first side surface 100S1 of the first semiconductor package 100 and the first semiconductor chip 130, and may not exist between the third side surface 100S3 and the first semiconductor chip 130.

In an embodiment, the first substrate 120 may be disposed side by side with the first semiconductor chip 130 on the redistribution layer 110. In the drawings, the first substrate 120 is shown as being exposed to the first side surface 100S1 of the first semiconductor package 100, but the present disclosure is not limited thereto. In the drawings, a surface exposed to the first side surface 100S1 of the first semiconductor package 100 of the first substrate 120 may also be covered with the first encapsulant 140. Additionally, although not illustrated, the first substrate 120 may be exposed to the second side surface 100S2 and/or the fourth side surface 100S4 of the first semiconductor package 100.

The first semiconductor chip 130 may be disposed on one surface of the redistribution layer 110, and may be electrically connected to the redistribution layer 110.

The first semiconductor chip 130 may be disposed between the wiring layers 122 of the first substrate 120 and the third side surface 100S3 of the first semiconductor package 100. Because the wiring layers 122 exist between the first semiconductor chip 130 and the first side surface 100S1 of the first semiconductor package 100, a distance between the first semiconductor chip 130 and the first side surface 100S1 of the first semiconductor package 100 may be greater than a distance between the first semiconductor chip 130 and the third side surface 100S3 of the first semiconductor package 100. Here, the distance between the components may be a minimum distance between the components. For example, the distance between the first semiconductor chip 130 and the first side surface 100S1 of the first semiconductor package 100 may be a distance between a surface of the first semiconductor chip 130 adjacent to the first side surface 100S1 of the first semiconductor package 100 and the first side surface 100S1 of the first semiconductor package 100. In addition, the distance between the first semiconductor chip 130 and the third side surface 100S3 of the first semiconductor package 100 may be a distance between a surface of the first semiconductor chip 130 adjacent to the third side surface 100S3 of the first semiconductor package 100 and the third side surface 100S3 of the first semiconductor package 100.

As described above, the second semiconductor package 200 may be disposed to deviate from the first semiconductor chip 130, and at least a portion of the first semiconductor chip 130 may not overlap the second semiconductor package 200 in a vertical direction.

The first semiconductor chip 130 may include the connection pad 130P, and the connection pad 130P may be disposed on the redistribution layer 110 in a face-down form so as to face the redistribution layer 110. A surface on which the connection pad 130P of the first semiconductor chip 130 is disposed may be referred to as an active surface, and a surface opposite to the active surface may be referred to as an inactive surface. The first semiconductor chip 130 may further include a known component such as a semiconductor substrate (e.g., a silicon substrate or the like), a plurality of individual elements, an internal circuit, or the like in addition to the connection pad 130P. The first semiconductor chip 130 may be directly connected to the redistribution layer 110 without a conductive bump, and the redistribution layer 110 may include a first via 113A that is in contact with the connection pad 130P and is electrically connected to the connection pad 130P. The first semiconductor chip 130 may be a system on chip (SOC), but the present disclosure is not limited thereto, and the first semiconductor chip may be another type of a semiconductor chip such as a logic chip, a memory chip, or the like.

The first encapsulant 140 may fix the first substrate 120 and the first semiconductor chip 130, and may protect the first substrate 120 and the first semiconductor chip 130. The first encapsulant 140 may cover at least a portion of an upper surface of each of the first substrate 120 and the first semiconductor chip 130 and at least a portion of a side surface of each of the first substrate 120 and the first semiconductor chip 130. An insulating material may be used as a material of the first encapsulant 140, and for example, the insulating material may be an epoxy molding compound (EMC), an Ajinomoto buildup film (ABF), or the like. As described above, the first encapsulant 140 may expose the third wiring layer 122C among the wiring layers 122 of the first substrate 120 that is closest to the second semiconductor package 200.

The protective layer 150 may be disposed on the other surface of the redistribution layer 110, and may protect the redistribution layer 110. The protective layer 150 may expose (i.e., not cover) the third redistribution layer 112C disposed at an outermost side of the redistribution layer 110, and the third redistribution layer 112C may be connected to the under bump structure 160 and/or the first conductive bump 170 through a region exposed to the protective layer 150. An insulating material may be used as a material of the protective layer 150, and for example, the insulating material may be a solder resist (SR), an ABF, or the like.

The under bump structure 160 may be disposed between the redistribution layer 110 and the first conductive bump 170 to improve connection reliability of the first conductive bump 170. The under bump structure 160 may include an under bump metal layer 161 disposed on the protective layer 150 and an under bump via 162 disposed in an opening of the protective layer 150 to connect the under bump metal layer 161 to the third redistribution layer 112C. The under bump via 162 may be disposed along a wall surface of the opening of the protective layer 150, or may fill the opening of the protective layer 150. A conductive material such as a metal or the like may be used as a material of the under bump structure 160, and the under bump structure 160 may include a single or a plurality of conductive layers.

The first conductive bump 170 may be disposed above the other surface of the redistribution layer 110, and may physically and/or electrically connect the first semiconductor package 100 to another component such as a main board or the like. For example, the first conductive bump 170 may be formed with solder, but the present disclosure is not limited thereto. Additionally, the first conductive bump 170 may have various shapes such as a ball, a land, a pin, and the like.

The passive element 180 may be disposed between first conductive bumps 170 above the other surface of the redistribution layer 110. The passive element 180 may be electrically connected to the third redistribution layer 112C disposed at a lowermost side of the redistribution layer 110. Additionally, the passive element 180 may be electrically connected to the first semiconductor chip 130 through the redistribution layer 110, and power stability, quality, or the like of the first semiconductor chip 130 may be improved. The passive element 180 may overlap the first semiconductor chip 130, and in this case, the passive element 180 may have a short electrical connection path with the first semiconductor chip 130. The passive element 180 may be a surface mounted component, and for example, the surface mounted component may be a multi-layer ceramic capacitor (MLCC), but the present disclosure is not limited thereto. Additionally, the number of passive elements 180 is not particularly limited, and may be a single or plural number.

The second substrate 210 may have a general structure known in a semiconductor package industry. For example, the second substrate 210 may be a printed circuit board (PCB), a redistribution substrate, or the like, and may include an insulating layer, wiring layers, vias, and the like. The second semiconductor chip may be flip-chip bonded or wire-bonded above the second substrate 210, or may be directly disposed on the second substrate 210 similar to the first semiconductor package 100.

The second semiconductor chip 230 may include a connection pad 230P, and the connection pad 230P may be disposed above the redistribution layer 110 in a face-down form so as to face the second substrate 210, or conversely, the connection pad 230P may be disposed above the redistribution layer 110 in a face-up form so as to face the second substrate 210. A surface on which the connection pad 230P of the second semiconductor chip 230 is disposed may be referred to as an active surface, and a surface opposite to the active surface may be referred to as an inactive surface. The second semiconductor chip 230 may further include a known component such as a semiconductor substrate (e.g., a silicon substrate or the like), a plurality of individual elements, an internal circuit, or the like in addition to the connection pad 230P. The second semiconductor chip 230 may be a memory chip such as a dynamic random access memory (DRAM), a static RAM (SRAM), or a flash memory, but the present disclosure is not limited thereto, and the second semiconductor chip 230 may be another type of a semiconductor chip such as a logic chip, a processor chip, or the like.

The second encapsulant 240 may fix the second semiconductor chip 230, and may protect the second semiconductor chip 230. The second encapsulant 240 may cover at least a portion of each of an upper surface and a side surface of the second semiconductor chip 230. An insulating material may be used as a material of the second encapsulant 240, and for example, the insulating material may be an epoxy molding compound (EMC), an Ajinomoto buildup film (ABF), or the like.

The second conductive bump 270 may physically and electrically connect the second semiconductor package 200 to the first substrate 120 of the first semiconductor package 100. The second conductive bump 270 may contact the third wiring layer 122C exposed to (i.e., not covered by) the first encapsulant 140, and may also contact the first encapsulant 140. For example, the second conductive bump 270 may be formed with solder, but the present disclosure is not limited thereto. Additionally, the second conductive bump 270 may have various shapes such as a ball, a land, a pin, and the like.

On the other hand, depending on a design, the second semiconductor chip 230 in a form of an unpackaged bare die may be disposed above the first semiconductor package 100 instead of the second semiconductor package 200, and this embodiment is also included in the present disclosure.

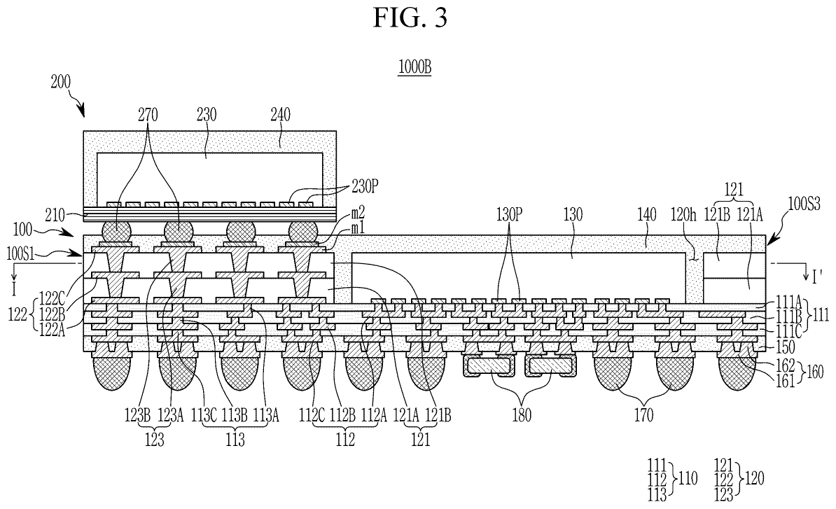

FIG. 3 is a cross-sectional view of a semiconductor package according to an embodiment of the present disclosure.

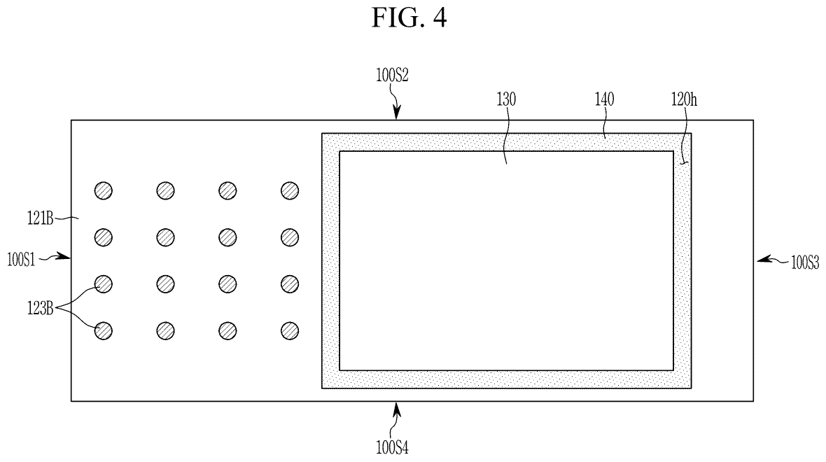

FIG. 4 is a plan view of the semiconductor package of FIG. 3 cut in a direction I-I′.

A first substrate 120 of the semiconductor package 1000B has a different structure from that of the semiconductor package 1000A. The first substrate 120 of the semiconductor package 1000B may have a cavity 120h extending from one surface to the other surface, and a first semiconductor chip 130 may be disposed within the cavity 120h. A method of forming the cavity 120h is not particularly limited, and laser processing, mechanical processing, or the like may be used. A first encapsulant 140 of the semiconductor package 1000B may fill a portion of the cavity 120h, and may cover at least a portion of the first semiconductor chip 130. Additionally, the first substrate 120 may be exposed to side surfaces 100S1, 100S2, 100S3 and 100S4 of a first semiconductor package 100. A distance from the cavity 120h to the first side surface 100S1 of the first semiconductor package 100 may be greater than a distance from the cavity 120h to the third side surface 100S3.

Descriptions of other components may be identically applied to the description of the semiconductor package 1000A of the present disclosure.

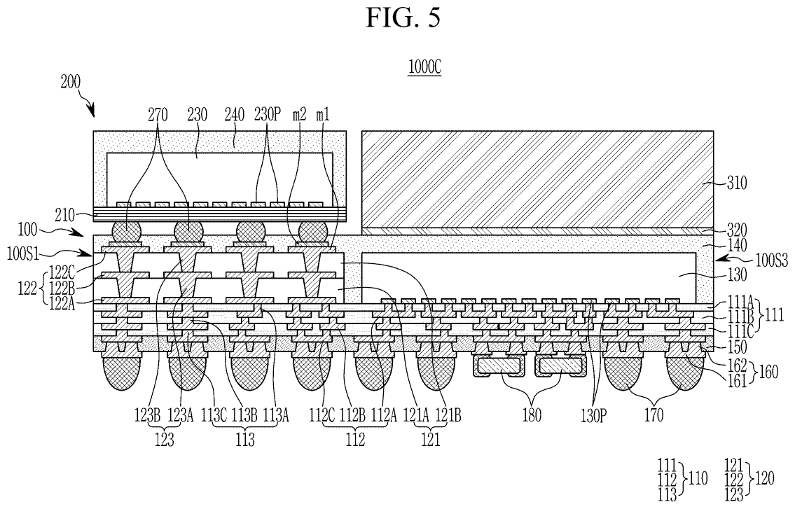

FIG. 5 is a cross-sectional view of a semiconductor package according to an embodiment of the present disclosure.

The semiconductor package 1000C may further include a heat dissipation structure 310 in addition to the first semiconductor package 100 and the second semiconductor package 200 of the semiconductor package 1000A.

The heat dissipation structure 310 may be disposed side by side with the second semiconductor package 200 above the first semiconductor package 100. At least a portion of the heat dissipation structure 310 may be disposed above the first semiconductor chip 130. In order to improve a heat dissipation characteristic, the heat dissipation structure 310 may be disposed above an entire region of the first semiconductor chip 130. As described above, at least a portion of the second semiconductor package 200 may be disposed above the first substrate 120.

In addition, the semiconductor package 1000C may further include a bonding layer 320 that is disposed between the first semiconductor package 100 and the heat dissipation structure 310 and bonds the first semiconductor package 100 and the heat dissipation structure 310 to each other. In the present disclosure, there may be no other configuration such as a backside redistribution layer of the first semiconductor package 100 above the first encapsulant 140, and the bonding layer 320 may be directly disposed on the first encapsulant 140 to contact the first encapsulant 140. A thermal interface material (TIM), a die attach film (DAF), or the like may be used as a material of the bonding layer 320, and the bonding layer 320 may include one or more of the materials.

The semiconductor package 1000C may more efficiently dissipate a heat generated from the first semiconductor chip 130 to the outside of the package through the heat dissipation structure 310 disposed above the first semiconductor chip 130. The heat dissipation structure 310 and bonding layer 320 may be similar applied to the previously described semiconductor packages 1000A and 1000B, as well as subsequently described semiconductor packages 1000D and 1000E.

Descriptions of other components may be identically applied to the description of the semiconductor package 1000A of the present disclosure.

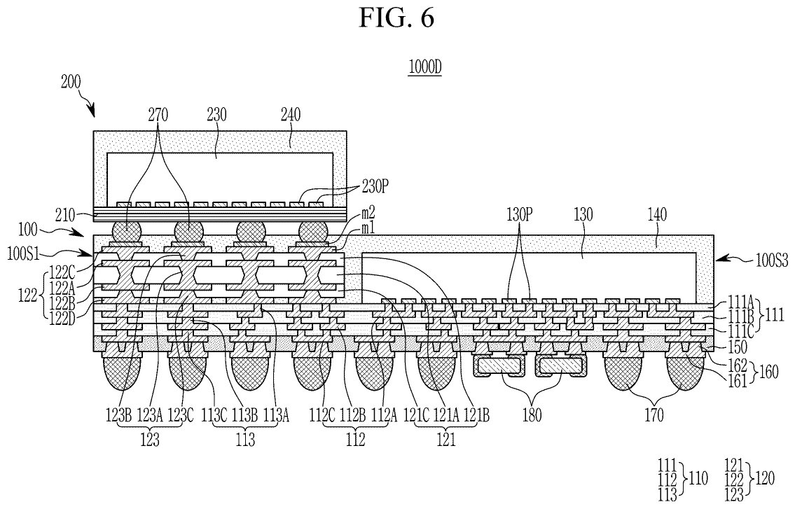

FIG. 6 is a cross-sectional view of a semiconductor package according to an embodiment of the present disclosure.

A first substrate 120 of the semiconductor package 1000D has a different structure from that of the semiconductor package 1000A. For example, the first substrate 120 of the semiconductor package 1000D may include a first insulating layer 121A, a first wiring layer 122A and a second wiring layer 122B each disposed on two surfaces of the first insulating layer 121A, first vias 123A penetrating the first insulating layer 121A to electrically connect the first wiring layer 122A to the second wiring layer 122B, a second insulating layer 121B covering the first wiring layer 122A, a third wiring layer 122C disposed on the second insulating layer 121B, second vias 123B penetrating the second insulating layer 121B to electrically connect a third wiring layer 122C to the first wiring layer 122A, a third insulating layer 121C covering the second wiring layer 122B, a fourth wiring layer 122D disposed on the third insulating layer 121C, and third vias 123C penetrating the third insulating layer 121C to electrically connect the fourth wiring layer 122D to the second wiring layer 122B. The first insulating layer 121A disposed in a middle of insulating layers 121 may be a core insulating layer having a thickness greater than those of other insulating layers 121B and 121C. Additionally, each of the first vias 123A penetrating the first insulating layer 121A may have an hourglass shape.

Descriptions of other components may be identically applied to the description of the semiconductor package 1000A of the present disclosure.

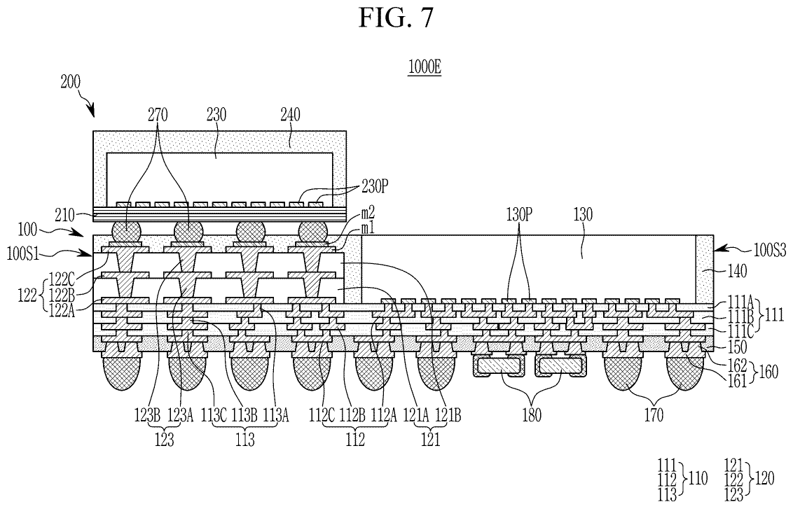

FIG. 7 is a cross-sectional view of a semiconductor package according to an embodiment of the present disclosure.

In a first semiconductor chip 130 of the semiconductor package 1000E, a surface opposite to a surface (e.g., an inactive surface) facing the redistribution layer 110 may be exposed to one surface of a first encapsulant 140. The inactive surface of the first semiconductor chip 130 may be exposed to the one surface of the first encapsulant 140 by grinding a portion of the first encapsulant 140 that covers the inactive surface of the first semiconductor chip 130.

In the semiconductor package 1000E, the first semiconductor chip 130 may not be covered with the first encapsulant 140, so that a heat generated from the first semiconductor chip 130 is more efficiently discharged to the outside of the package. The semiconductor package 1000E may further include the heat dissipation structure 310 and the bonding layer 320 like the semiconductor package 1000C. In this case, the bonding layer 320 may contact the inactive surface of the first semiconductor chip 130. In contrast to the semiconductor package 1000A for example, the height of the first substrate 120 may be reduced with respect to the height of the first semiconductor chip 130 in the semiconductor package 1000E. For example, as illustrated in FIG. 7, the surface of the first substrate 120 facing the second semiconductor chip 230 may not be coplanar with the inactive surface of the first semiconductor chip 130.

Descriptions of other components may be identically applied to the descriptions of the semiconductor packages 1000A and 1000D of the present disclosure.

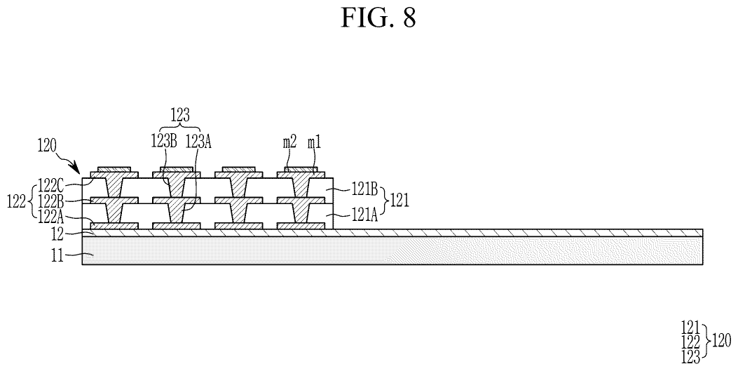

FIGS. 8 to 15 are views for describing a manufacturing process of the semiconductor package of FIG. 5.

First, referring to FIG. 8, the first substrate 120 is disposed above a first carrier substrate 11. Silicon, glass, ceramic, plastic, or the like may be used as a material of the first carrier substrate 11, and an adhesive layer 12 such as an adhesive, an adhesive tape, or the like may be disposed on one surface of the first carrier substrate 11. The first substrate 120 may be disposed above the first carrier substrate 11 so that a surface where the first insulating layer 121A and the first wiring layer 122A are disposed is adhered and fixed to the adhesive layer 12. When the first substrate 120 has the ETS structure, a surface attached to the adhesive layer 12 of the first substrate 120 may be flat, so that it is easy to attach the first substrate 120 to the adhesive layer 12.

Before the first substrate 120 is disposed above the first carrier substrate 11, a step of manufacturing the first substrate 120 may be performed, and the first substrate 120 may be formed by sequentially performing a step of forming the first wiring layer 122A, a step of forming the first insulating layer 121A to cover the first wiring layer 122A, a step of forming the first via 123A penetrating the first insulating layer 121A, a step of forming the second wiring layer 122B on the first insulating layer 121A, a step of forming the second insulating layer 121B on the first insulating layer 121A to cover the second wiring layer 122B, a step of forming the second via 123B penetrating the second insulating layer 121B, and a step of forming the third wiring layer 122C on the second insulating layer 121B.

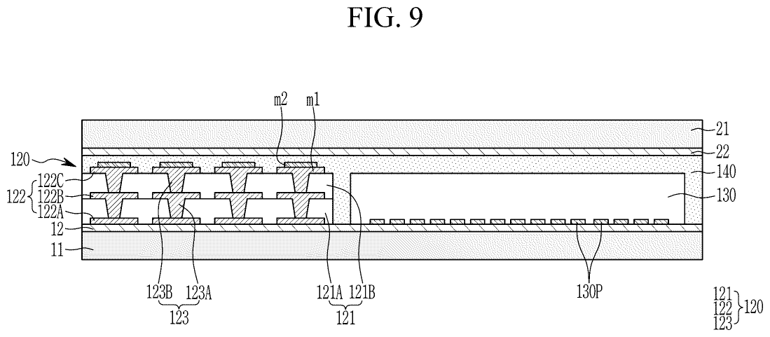

Next, referring to FIG. 9, the first semiconductor chip 130 is disposed above the first carrier substrate 11 and adjacent to the first substrate 120. The first substrate 120 and the first semiconductor chip 130 are subsequently molded with the first encapsulant 140. The first semiconductor chip 130 may be disposed above the first carrier substrate 11 so that an active surface where the connection pad 130P is adhered and fixed to the adhesive layer 12. Compression molding, transfer molding, or the like may be used as a method of molding the first substrate 120 and the first semiconductor chip 130. Thereafter, a second carrier substrate 21 is attached above the first encapsulant 140. Silicon, glass, ceramic, plastic, or the like may be used as a material of the second carrier substrate 21, and an adhesive layer 22 such as an adhesive, an adhesive tape, or the like may be disposed on one surface of the second carrier substrate 21 so that the adhesive layer 22 is attached to the first encapsulant 140.

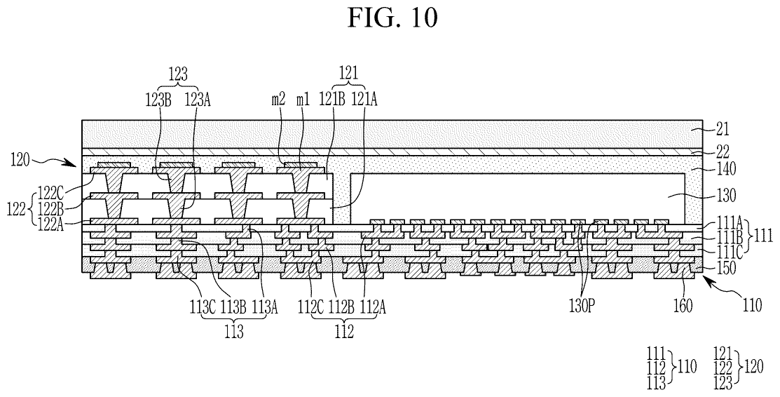

Next, referring to FIG. 10, the first carrier substrate 11 is removed, and the redistribution layer 110, the protective layer 150, and the under bump structure 160 are sequentially formed on the first substrate 120 and the first semiconductor chip 130. The first carrier substrate 11 may be removed together with the adhesive layer 12 by performing heat treatment, ultraviolet ray irradiation, or the like on the adhesive layer 12. Surfaces of the first substrate 120, the first semiconductor chip 130, and the first encapsulant 140 exposed by removing of the first carrier substrate 11 may be coplanar with each other.

The redistribution layer 110 may be formed by sequentially performing a step of forming the first insulating layer 111A on the first substrate 120 and the first semiconductor chip 130, a step of forming the first via 113A penetrating the first insulating layer 111A, a step of forming the first wiring layer 112A on the first insulating layer 111A, a step of forming the second insulating layer 111B on the first insulating layer 111A to cover the first wiring layer 112A, a step of forming the second via 113B penetrating the second insulating layer 111B, a step of forming the second redistribution layer 112B on the second insulating layer 111B, a step of forming the third insulating layer 111C on the second insulating layer 111B to cover the second redistribution layer 112B, a step of forming the third via 113C penetrating the third insulating layer 111C, and a step of forming the third redistribution layer 112C on the third insulating layer 111C.

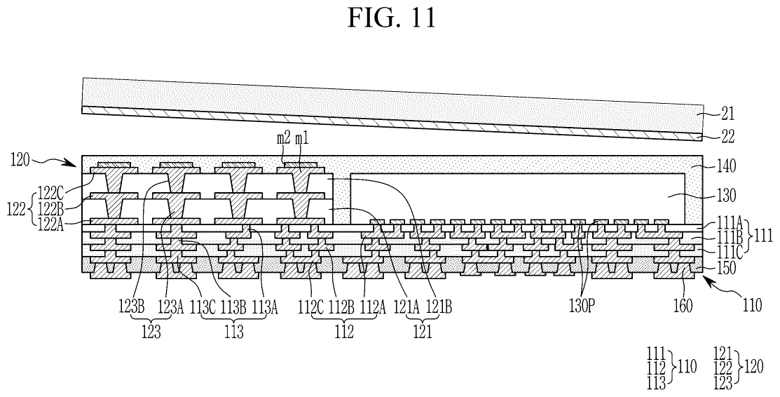

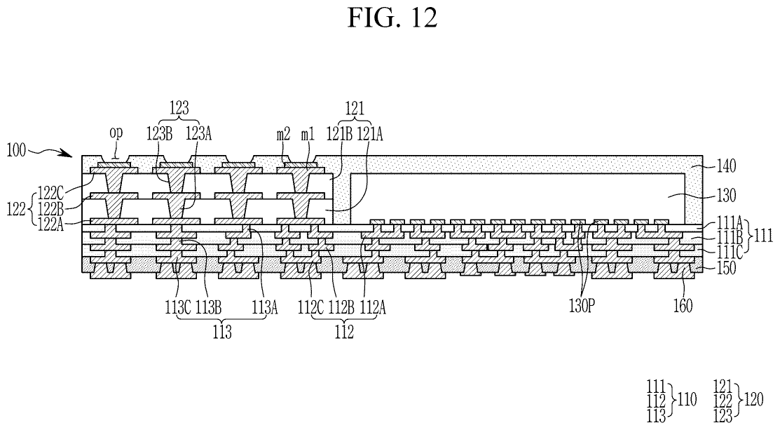

Next, referring to FIG. 11 and FIG. 12, the second carrier substrate 21 is removed, and an opening op for exposing the third wiring layer 122C is formed at the first encapsulant 140. The second carrier substrate 21 may also be removed together with the adhesive layer 22 by performing heat treatment, ultraviolet ray irradiation, or the like on the adhesive layer 22. The opening op of the first encapsulant 140 may be formed using a CO₂ laser, but the present disclosure is not limited thereto, and the opening op of the first encapsulant 140 may be formed using another method such as mechanical processing or the like.

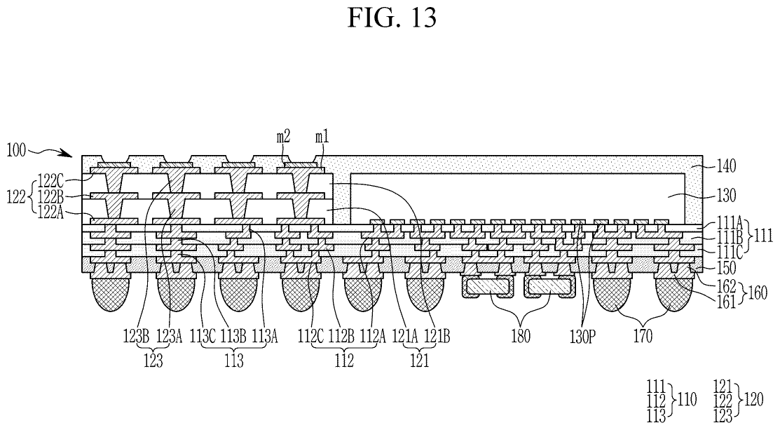

Next, referring to FIG. 13, the first conductive bump 170 is formed above the redistribution layer 110, and the passive element 180 is attached above the redistribution layer 110. For example, the passive element 180 may be attached with a solder paste.

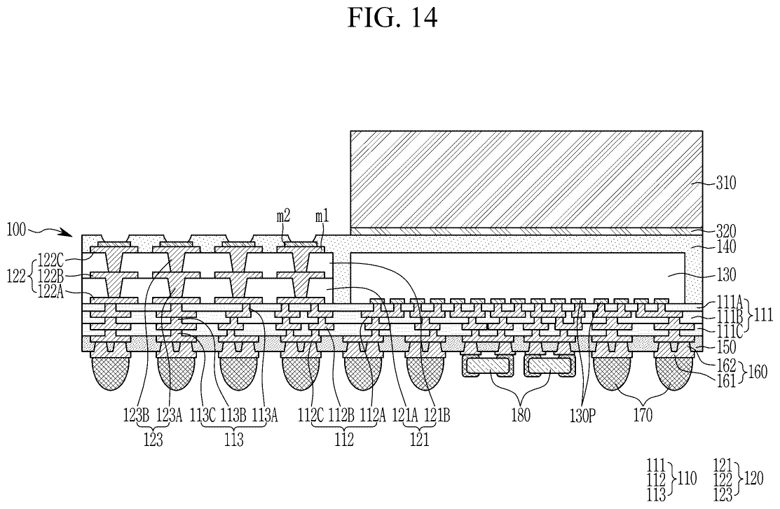

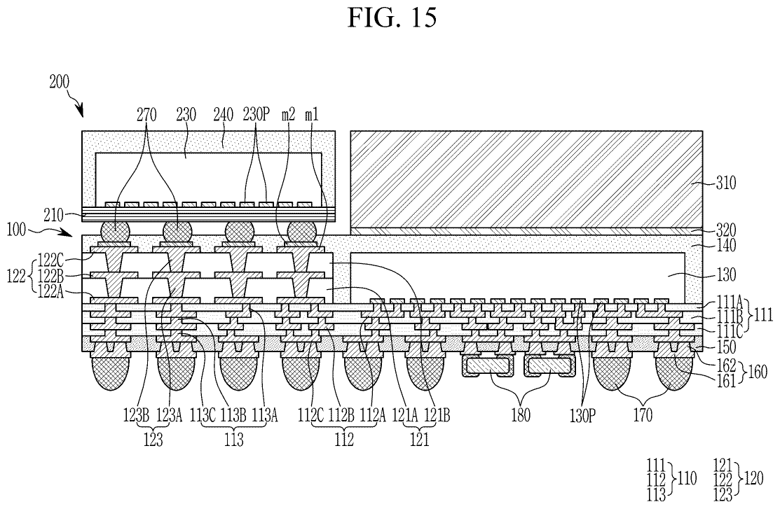

Next, referring to FIG. 14 and FIG. 15, the heat dissipation structure 310 is disposed above the first encapsulant 140 so that at least a portion of the heat dissipation structure is disposed above the first semiconductor chip 130. The heat dissipation structure 310 may be attached above the first encapsulant 140 through the bonding layer 320. When the semiconductor package of an embodiment that does not include the heat dissipation structure 310 is manufactured, a step of disposing the heat dissipation structure 310 may be omitted. Additionally, the second semiconductor package 200 is disposed above the first substrate 120. The second semiconductor package 200 may be disposed on the first semiconductor package 100 through the second conductive bump 270. The second semiconductor package 200 may be manufactured separately from the first semiconductor package 100 and then may be disposed on the first semiconductor package 100. For example, the second semiconductor package 200 may be manufactured by disposing the second semiconductor chip 230 on one surface of the second substrate 210, molding the second semiconductor chip 230 with the second encapsulant 240, and then forming the second conductive bump 270 on the other surface of the second substrate 210.

An order of some processes in the manufacturing process of the semiconductor package may be changed so that some processes are implemented, and this embodiment is also included in the present disclosure.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a first semiconductor package that includes a redistribution layer, a substrate disposed on the redistribution layer and including a plurality of wiring layers, a first semiconductor chip disposed on the redistribution layer, and an encapsulant covering at least a portion of each of the substrate and the first semiconductor chip; and
a second semiconductor package that is disposed on the first semiconductor package and includes a second semiconductor chip,
wherein the first semiconductor package includes a first side surface and a second side surface facing the first side surface, and
wherein the plurality of wiring layers are disposed adjacent to the first side surface of the first semiconductor package, the first semiconductor chip is disposed between the plurality of wiring layers and the second side surface of the first semiconductor package, and a distance between the first semiconductor chip and the first side surface of the first semiconductor package is greater than a distance between the first semiconductor chip and the second side surface of the first semiconductor package.

2. The semiconductor package of claim 1, wherein the encapsulant does not cover a wiring layer among the plurality of wiring layers closest to the second semiconductor package, the second semiconductor package further includes a conductive bump that electrically connects the second semiconductor package to the first semiconductor package, and the conductive bump is in contact with the wiring layer not covered by the encapsulant.

3. The semiconductor package of claim 1, wherein at least a portion of the first semiconductor chip does not overlap the second semiconductor package in a vertical direction.

4. The semiconductor package of claim 1, wherein the substrate is disposed side by side with the first semiconductor chip on the redistribution layer.

5. The semiconductor package of claim 1, wherein the substrate has a cavity extending from one surface to the other surface of the substrate, and the first semiconductor chip is disposed within the cavity.

6. The semiconductor package of claim 1, wherein the substrate includes a first wiring layer, a first insulating layer covering the first wiring layer, a second wiring layer disposed on the first insulating layer and electrically connected to the first wiring layer, a second insulating layer covering the second wiring layer, and a third wiring layer disposed on the second insulating layer and electrically connected to the second wiring layer.

7. The semiconductor package of claim 6, wherein a surface of the substrate facing the redistribution layer and a surface of the first semiconductor chip facing the redistribution layer are coplanar.

8. The semiconductor package of claim 1, wherein the substrate includes a first insulating layer, a first wiring layer and a second wiring layer each disposed on two surfaces of the first insulating layer, a second insulating layer covering the first wiring layer, a third wiring layer disposed on the second insulating layer and electrically connected to the first wiring layer, a third insulating layer covering the second wiring layer, and a fourth wiring layer disposed on the third insulating layer and electrically connected to the second wiring layer.

9. The semiconductor package of claim 1, wherein the first semiconductor chip includes a connection pad, and the redistribution layer includes a via in contact with the connection pad to be electrically connected to the connection pad.

10. The semiconductor package of claim 1, wherein the first semiconductor package further includes a passive element disposed above a surface opposite to a surface of the redistribution layer facing the first semiconductor chip to be electrically connected to the first semiconductor chip.

11. The semiconductor package of claim 1, wherein a surface opposite to a surface of the first semiconductor chip facing the redistribution layer is coplanar with one surface of the encapsulant.

12. The semiconductor package of claim 1, further comprising a heat dissipation structure that is disposed side by side with the second semiconductor package above the first semiconductor package,
wherein at least a portion of the heat dissipation structure is disposed above the first semiconductor chip.

13. The semiconductor package of claim 12, further comprising a bonding layer that is disposed between the first semiconductor package and the heat dissipation structure.

14. The semiconductor package of claim 13, wherein the bonding layer is in contact with the encapsulant.

15. A semiconductor package comprising:
a first semiconductor package that includes a redistribution layer, a first substrate that is disposed on the redistribution layer to be electrically connected to the redistribution layer and includes a plurality of insulating layers and a plurality of wiring layers, a first semiconductor chip disposed on the redistribution layer and electrically connected to the redistribution layer, and a first encapsulant covering at least a portion of each of the first substrate and the first semiconductor chip; and
a second semiconductor package that is disposed on the first semiconductor package and includes a second substrate, a second semiconductor chip disposed on a first surface of the second substrate to be electrically connected to the second substrate, a second encapsulant covering the second semiconductor chip, and a conductive bump disposed on a second surface of the second substrate,
wherein the first encapsulant does not cover a wiring layer among the plurality of wiring layers closest to the second semiconductor package, the conductive bump contacts the wiring layer not covered by the first encapsulant to electrically connect the second semiconductor package to the first substrate, and at least a portion of the first semiconductor chip does not overlap the second semiconductor package in a vertical direction.

16. The semiconductor package of claim 15, wherein a region not covered by the first encapsulant of the wiring layer closest to the second semiconductor package includes a plurality of conductive layers including different materials.

17. A semiconductor package comprising:
a first semiconductor package that includes a redistribution layer, a substrate disposed on the redistribution layer and electrically connected to the redistribution layer, a first semiconductor chip disposed on the redistribution layer and electrically connected to the redistribution layer, and an encapsulant covering at least a portion of each of the substrate and the first semiconductor chip;
a second semiconductor package that is disposed on the first semiconductor package to be electrically connected to the substrate and includes a second semiconductor chip; and
a heat dissipation structure that is disposed side by side with the second semiconductor package above the first semiconductor package,
wherein at least a portion of the second semiconductor package is disposed above the substrate, and at least a portion of the heat dissipation structure is disposed above the first semiconductor chip.

18. The semiconductor package of claim 17, further comprising a bonding layer that is disposed between the first semiconductor package and the heat dissipation structure.

19. The semiconductor package of claim 18, wherein the bonding layer is in contact with the encapsulant.

20. The semiconductor package of claim 18, wherein the bonding layer includes a thermal interface material (TIM).
